(19) United States
(12) Patent Application Publication
(10) Pub. No.: US 2011/0093763 A1
(43) Pub. Date: Apr. 21, 2011

(54) ELECTRICAL CIRCUIT COMPRISING A DYNAMIC RANDOM ACCESS MEMORY (DRAM) WITH CONCURRENT REFRESH AND READ OR WRITE, AND METHOD TO PERFORM CONCURENT

(75) Inventor: Roelof Herman Willem Salters, Waalre (NL)

(73) Assignee: NXP B.V., Eindhoven (NL)

(21) Appl. No.: 12/999,402

(22) PCT Filed: Jun. 17, 2009
(86) PCT No.: PCT/IB2009/052567

§ 371 Date: Dec. 16, 2010

(30) Foreign Application Priority Data
Jun. 17, 2008 (EP) 08158365.0

(51) Int. Cl. H03M 13/09; G11C 11/406

(52) U.S. Cl. 714/758; 365/222; 714/E11.03

(57) ABSTRACT

Electrical circuit comprising: A Dynamic Random Access Memory comprising a plurality of memory cells; An associated device connected to said memory via a data bus; Memory cell refresh means, in which: A refresh access is employed to refresh stored data in a memory cell, with the aid of said refresh means; A data access is employed to exchange data between the associated device and a memory cell via said data bus, said data access comprising a read access or a write access, wherein: The circuit comprises conflict check means that, for a given memory cell, detect and communicate a conflict between a requested access of a first type to said cell, said first type being one of a data access and a refresh access, and an ongoing access of a second type to said cell, said second type being the other of a data access and a refresh access.

### FIELD OF THE INVENTION

The invention relates to the field of volatile memory devices and particularly to Dynamic Random Access Memories (DRAMs). More specifically, the invention relates to DRAMs with refreshing means for refreshing the memory. In particular, the invention relates to an electrical circuit comprising:
A Dynamic Random Access Memory comprising a plurality of memory cells;
An associated device connected to said memory via a data bus;
Memory cell refresh means,
   in which:
A refresh access is employed to refresh stored data in a memory cell, with the aid of said refresh means;
A data access is employed to exchange data between the associated device and a memory cell via said data bus, said data access comprising a read access or a write access.

### BACKGROUND OF THE INVENTION

A DRAM is a type of volatile memory. This means that when the memory is powered off, the information stored in the DRAM will rapidly fade away and be lost, as the memory cells of such a memory make use of a capacitor to store information. A capacitor can be charged or not charged, representing a bit (0 or 1) of information. As a charged capacitor inherently leaks charge, the charged capacitors of such a DRAM have to be recharged before too much charge has leaked away from the capacitor, otherwise it will not be possible to make a clear difference between a charged capacitor and a non charged capacitor, meaning that the information stored in the memory will be lost. It is this principle that necessitates recharging of the charged capacitors of the memory cells in time. There are a lot of operating modes that can be chosen to recharge the capacitors in time. The recharging can for instance be done on a block-by-block basis, meaning that the capacitors of the memory cells of parts of the

DRAM comprising more than one memory cell (“a block”) are recharged in a specific order, or by recharging all the capacitors of the memory cells of the whole memory in one operation. The recharging of the charged memory cells is also known as refreshing. By its nature the refresh operations, or refreshing cycles, are ongoing procedures. All the memory cells of the memory have to be refreshed in time, again and again.

In practice, memory data are accessed via read or write operations. During a read operation, information in the memory is read from the memory, and during a write operation, information is stored into the memory. Read, write and refresh operations are generally administered by a controller. Because it is impossible to concurrently perform refresh operations and read/write operations on given memory cells, the controller will have to suspend read/write operations from or to these given memory cells while it conducts a periodic refresh of these memory cells. This means that all read/write operations to the memory cells that are to be refreshed are suspended as long as the refresh cycle is going on (a so-called interruptive refresh cycle). On the other hand, in sleep mode, when the DRAM is not being read/write accessed, refreshing does not have to be interrupted. Since read/write traffic has to be regularly interrupted because of the necessary refresh operations, this greatly reduces the availability (bandwidth) of the memory. This is highly disadvantageous.

The number of memory cells in a DRAM is ever increasing. Due to the fact that there is a limitation on the power consumption of the memory, there is a limitation to the number of memory cells that can be refreshed in any one refresh cycle. Next to that, the time between two refreshes of a memory cell does not increase, as the time between two refreshes is dictated by physics, i.e. the leakage current of said capacitors of the memory cells. As a consequence, an ever increasing percentage of available time will be lost due to the refresh operations, during which one has to delay all read or write operations to the memory cells that are to be refreshed.

A further disadvantage is that, in a system having more then one DRAM, all the memories have to be refreshed under external control according to a “worst case” scenario. This means that all memories will be refreshed before it becomes possible for the capacitors of the memory cells of one DRAM to have leaked too much charge to become unreliable. The leakage of the charge of a capacitor of a memory cell will, for example, be exponential, dependent on the actual temperature of the memory. The higher the temperature of the DRAM, the sooner the charge of the charged capacitor will leak away. As specifications are drawn up so as to ensure that refresh occurs before too much charge is lost in the capacitors of the memory cells, the “worst case” scenario, i.e. the scenario that the charged memory cells of the DRAM might have lost their charge because of the highest possible temperature of one of the DRAMs, dictates that all the DRAMs will be refreshed at a time when it might not be necessary for all of them, because the actual temperature of a significant number of the DRAMs in the system might be lower, meaning that a refresh is not yet necessary. This means that an even greater percentage of time will be spent refreshing, during which time one will have to suspend read or write operations from or to the memory cells which are being refreshed.

### SUMMARY OF THE INVENTION

It is an object of the invention to overcome the aforementioned disadvantages.

In particular, it is an advantage of the invention to increase the percentage of time that the DRAM is available for read or write operations.

Moreover, it is an advantage of the invention that, in a system having several DRAMs, every DRAM can be refreshed according to its own circumstances, such as temperature.

These and other objects are achieved in an electrical circuit comprising:
A Dynamic Random Access Memory comprising a plurality of memory cells;
An associated device connected to said memory via a data bus;
Memory cell refresh means,
   in which:
A refresh access is employed to refresh stored data in a memory cell, with the aid of said refresh means;
A data access is employed to exchange data between the associated device and a memory cell via said data bus, said data access comprising a read access or a write access,
   characterized in that:

The circuit comprises conflict check means that, for a given memory cell, detect and communicate a conflict between a requested access of a first type to said cell or group of cells, said first type being one of a data access and a refresh access, and an ongoing access of a second type to said cell, said second type being the other of a data access and a refresh access.

When a conflict is detected by said conflict check means, these will communicate a conflict signal that can be used to delay a requested read or write access to a given memory cell when a memory cell is already being accessed for a refreshing operation, or to delay a requested refresh access to a given memory cell when a memory cell is already being accessed for a read or write operation.

The invention is based on the insight that, in a DRAM, refreshing and read or write operations can be performed concurrently with the aid of certain conflict check architecture. This means that a situation in which one has to suspend all the read or write accesses to memory cells that are to be refreshed during an interruptive refresh cycle of the DRAM will no longer be necessary. As a result, the relatively large amounts of bandwidth lost to refresh operations will no longer be wasted.

The concurrent performance of read/write and refresh accesses upon the DRAM also means that the refreshing can be controlled internally on the DRAM itself and external control of, for instance, a controller may not be needed any more. The internal refreshing mode was already known for DRAMs in sleep mode, but the use of internal refreshing in normal operation mode, when read or write operations are to be performed, is novel in this art.

As opposed to the “worst case” specifications drawn up to refresh all the DRAMs in the system in time according to the worst case scenario for one of them, the present invention allows a scenario whereby each individual DRAM in the system can do its refreshes at the appropriate rate for that specific DRAM. This again minimizes the impact of refreshing on the performance of a system comprising more than one DRAM, as well as the power dissipated for refresh in such a system, as, in total, less refreshes of the DRAMs will be necessary.

In an embodiment of the invention, the conflict check means comprise:
Petition means, for sending an outgoing status flag concurrently with said requested access of the first type to said memory cell;
Decision means, for determining if, for said memory cell, said requested access of a first type conflicts with said ongoing access of a second type;
Indicating means, for returning to the petition means a return status flag, indicating whether or not said access of a first type was allowed by said decision means.

In one such embodiment, the conflict check means comprise Cyclic Redundancy Check (CRC) means. The skilled artisan will be familiar with the concept and application of a CRC; nevertheless, for the sake of completeness, reference is made to, for example, http://en.wikipedia.org/wiki/cyclic_redundancy_check and http://www.ross.net/crc/ from which more information on this topic can be gleaned. This particular embodiment of the invention has the advantage that, if a CRC protection is already included in the data transmission between the DRAM and the associated device, the communicated conflict can be a CRC error signal. In case a particular requested read or write access conflicts with an ongoing refresh access to a given memory cell of the memory, a cyclic redundancy error signal, just as if there was an error in the transmission of data, is communicated. The failed read or write access can then be reissued just as it is the case when an error in the transmission of data would have occurred.

In another embodiment of the invention, the conflict check means exploit the use of a parity bit or a checksum.

Another embodiment of an electrical circuit according to the invention is characterized in that:
Said memory is located in a housing having a plurality of connection pins, at least some of said pins serving to allow the memory to be electrically connected to at least said associated device;
Said conflict check means comprise signal means for providing an electrical signal to at least one of said pins in the event of a detected conflict.

In this scenario, a detected conflict between a requested access and an ongoing access to a given memory cell can be communicated through (at least) one of the DRAM connection pins, which thus assumes the role of a “busy pin”. Said electrical signal may, for example, be a voltage signal, which, for example, is detected and interpreted by said associated device.

The invention also provides a method of performing refreshing concurrently with reading or writing of a DRAM having refreshing circuitry, which method comprises the steps of:
Detecting if there is a conflict between a read or write access and a refresh access for a given memory cell,
Communicating an error signal if there is a conflict,
Reissuing the read or write access to said cell in case the conflict was caused by a read or write access during an ongoing refresh access to said cell and
Delaying the refresh access to said cell in case the conflict was caused by a refresh access during an ongoing read or write access to said cell.

The present invention further comprises a Dynamic Random Access Memory suitable for use in an electrical circuit of the present invention.

These and other aspects of the invention will be apparent from and elucidated with reference to the embodiment(s) described hereinafter.

### BRIEF DESCRIPTION OF THE DRAWINGS

In the following section, the invention will be described by way of examples of its embodiments with reference to the attached drawings, in which:

FIG. 1 shows a schematic representation of a prior art DRAM and an associated device communicating therewith;

FIG. 2 shows a schematic representation of one embodiment of the present invention.

In the Figures, like reference numerals are used to indicate like features.

### DETAILED DESCRIPTION OF EMBODIMENTS

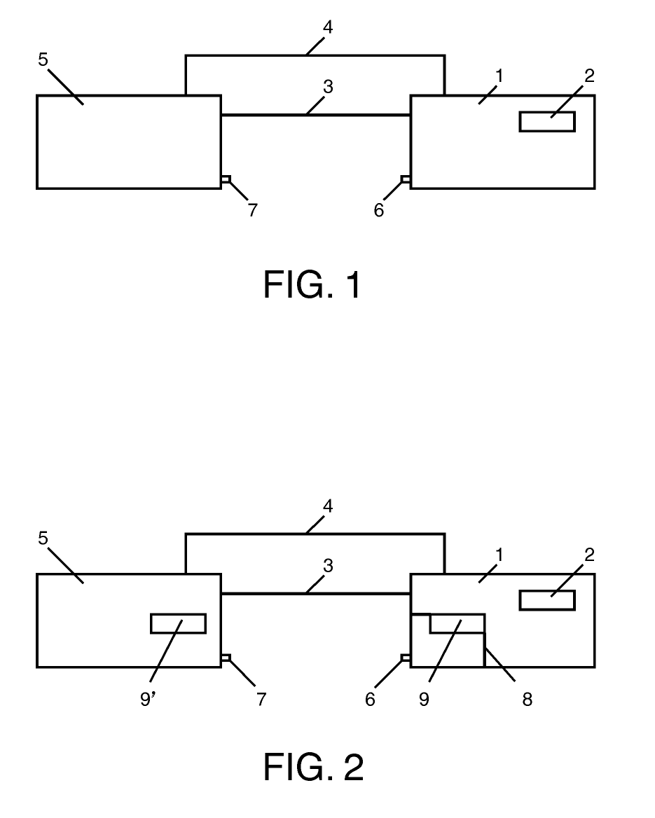

With reference to FIG. 1, a prior art DRAM (1) comprising a plurality of memory cells is shown. Every memory cell represents one bit of information which can be stored into the memory. At present a DRAM (1) typically has a size of 512 Mbit or 1 Gbit. Examples are the commercially available 512 Mbit DRAM, according to the DDR2 standard, made by Samsung (serial number: K4T56083QF-GD5) and the 1 Gbit DRAM, according to the DDR3 standard, also made by Samsung (serial number: K4B1G0846C). DRAMs with a memory size of 4 Gbit are currently being developed, but, at present, these DRAMs are not commercially available. For the near future, standardizations for DRAMs of 16 Gbit have already been drawn up, so that designers know what is expected when designing DRAMs of such a size. The DRAM (1) also comprises memory cell refresh means (2). When the memory is in sleep mode, i.e. when there are no read operations from and write operations to the memory cells of the DRAM (1), the refresh means (2) take care of an automated periodic refresh of the memory cells. When the memory is not in sleep mode, i.e. when the memory is used for reading information from given memory cells or for writing information to given memory cells, the refresh means (2) and the reading of, or writing to, given memory cells will be under external control (whereby refreshing the memory cells occurs in time and according to some protocol). One possibility is to refresh the entire memory, i.e. all the memory cells of the DRAM, in one operation, during which all the possible read or write accesses to the memory are suspended. Another possibility is to refresh parts of the memory comprising more than one memory cell (“a block”) in a specific order on a block-by-block basis; during the refreshing of the memory cells of a given block, all potential read or write accesses to the memory cells of that block are suspended. At present, it is thought to be necessary that all the memory cells of the DRAM (1) have to be refreshed at least once every 256 ms. Depending on the number of bits to be refreshed during one refresh cycle and assuming that the refreshing takes place at regular intervals, this would lead to a refresh rate of, for example, every 3.9 μs, 7.8 μs or 15.6 μs. The refreshing means generally need an amplifier for every bit that has to be refreshed. This means that when a block or “bank” of memory cells of for instance 16,000 memory cells have to be refreshed, 16,000 amplifiers are needed at the same time. This has an enormous impact on the energy dissipation of the system. It might even be possible that the employed power supply cannot cope with such a load, in which case broader power supply lines or more power supply pins might be necessary. Because of this, noise might also be introduced into the system, which is highly undesirable. That's why current standards prefer refreshing not too many memory cells during one refresh cycle.

The DRAM is connected to an associated device (5) via a data bus (3) and a command and control bus (4). The associated device (5) is a controller, but can in principle be any appropriate device such as a processor chip, an ASIC chip, etc. It's this prior art controller that administers refresh and read or write accesses to given memory cells; the memory itself doesn't take any part in this. The controller allocates resources by reserving time-slots for a periodic refresh action. During such a time slot, the memory cells of part (or the whole) of the memory are refreshed, during which activity, as described hereinabove, the controller stops all the read or write accesses to the given memory cells which are being refreshed. Only if the time slot is over will read or write accesses to these memory cells be allowed again. The data bus (3) is used to transfer data read from the memory (1) to the associated device (5) and to transfer data to be written into the memory (1) from the device (5) to the memory (1). The width of the data bus (3) is currently 4, 8, 16 and sometimes 32 bits. The command and control bus (4) can, for example, be used for commands, the exchange of addresses and the transfer of clock signals. FIG. 1 also depicts two pins (6, 7) on the DRAM and associated device (5), respectively. Of course both the DRAM and the controller have more pins, but in FIG. 1 only these two are depicted. Current DRAMs have, for example, 60 pins (e.g. DDR2 DRAM, JEDEC package MO207-DJ-z).

In FIG. 2, an embodiment of the present invention is illustrated. Again a DRAM (1) having refreshing circuitry (2) connected to an associated device (5) via a data bus (3) and a command and control bus (4) is illustrated. Also, just for illustrating purposes, only two pins (6, 7) are illustrated. The DRAM (1) of the present invention comprises conflict check means (8). These conflict check means (8) detect and communicate a conflict between a read or write access and a refresh access to a given memory cell of the DRAM (1). It is these conflict check means (8) that make it possible for the reading or writing of memory cells to take place concurrently with refreshing of the memory cells. If a conflict is detected and communicated, a read or write access can be reissued by the associated device (5) in case the conflict was caused by a read or write access during an ongoing refresh access, and a refresh access can be delayed in case the conflict was caused by a refresh access during an ongoing read or write access. This delaying of the refresh access may be done by the refresh circuitry of the DRAM (1) or use can be made of a special delay circuit known to the person skilled in the art. There are no time-slots, dictated by the controller, in which all the read or write accesses are suspended to memory cells that are being refreshed. Instead, refreshing can now be an ongoing process. The conflict check means (8) of the DRAM (1) might be any circuitry to detect a conflict between different accesses. The circuitry might for instance be a known comparison circuit to compare the addresses of the accesses. Because now the controller doesn't have to control the refreshing and handling of conflicts between read or write accesses and refresh accesses anymore, the associated device (5) can be made less complicated than the controller of the prior art.

According to the present invention, conflict check means (8) in FIG. 2 comprise Cyclic Redundancy Check (CRC) means (9). Because of the ever increasing high speed interfaces between the DRAM (1) and an associated device (5), such as a controller, communicating therewith, more and more transmission errors of the transferred data are likely to occur. To be able to detect these errors, a CRC (or parity bit/checksum) can be included in the data transmission between the DRAM (1) and said associated device (5). At the moment, the standardization body JEDEC (JEDEC Solid State Technology Association) is discussing a new standardization related to the next generation of DRAMs (namely DDR4). It is foreseen that, in DDR4, a CRC protection will be included in the data to detect transmission errors in this data. According to the invention, the aforementioned conflict check means (8) can exploit the presence of this CRC, and the aforementioned error signal can be a CRC error signal. FIG. 2 shows that the associated device (5) also has CRC means (9′) to be able to include a CRC in the data. It allows a CRC error signal to be recognized as such.

In another embodiment of the invention, the conflict check means (8) comprise one or more pins (6, 7). The detection of a conflict between a read or write access and a refresh access to a given memory cell can then be communicated via one or more pins (6, 7). An example of such a pin might be a busy pin. These pins (6, 7) might be connected via a signal line.

Although preferred embodiments of the memory, method, and apparatus of the present invention have been illustrated in the accompanying drawings and described in the foregoing detailed description, it is understood that the invention is not limited to the embodiments disclosed, but is capable of numerous rearrangements, modifications, and substitutions without departing from the spirit of the invention as set forth and defined by the following claims. The skilled person will for example understand that the command and control bus (4) described herein can also exchange other information and signals than the information and signals as described hereinabove. The invention is also not limited to a memory (1) having internal conflict circuitry (9); the conflict check means (9) may be external or part of another device. It will also be understood that the conflict check means (9) may comprise any circuitry that is capable of detecting a requested access (of one type) of a memory cell during an ongoing access (of another type).

1. Electrical circuit comprising:
a Dynamic Random Access Memory comprising a plurality of memory cells;
an associated device connected to said memory via a data bus;
memory cell refresh means,
in which:
a refresh access is employed to refresh stored data in a memory cell, with the aid of said refresh means;
a data access is employed to exchange data between the associated device and a memory cell via said data bus, said data access comprising a read access or a write access,
characterized in that:
the circuit comprises conflict check means that, for a given memory cell, detect and communicate a conflict between a requested access of a first type to said cell, said first type being one of a data access and a refresh access, and an ongoing access of a second type to said cell, said second type being the other of a data access and a refresh access.

2. Electrical circuit according to claim 1, characterized in that said conflict check means comprise:
petition means, for sending an outgoing status flag concurrently with said requested access of the first type to said memory cell;
decision means, for determining if, for said memory cell, said requested access of a first type conflicts with said ongoing access of a second type;
indicating means, for returning to the petition means a return status flag, indicating whether or not said access of a first type was allowed by said decision means.

3. Electrical circuit according to claim 2, characterized in that said conflict check means comprise Cyclic Redundancy Check means.

4. Electrical circuit according to claim 2, characterized in that said conflict check means exploit the use of an indicator selected from the group comprising a parity bit and a checksum.

5. Electrical circuit according to claim 1, characterized in that:
said memory is located in a housing having a plurality of connection pins, at least some of said pins serving to allow the memory to be electrically connected to at least said associated device;
said conflict check means comprise signal means for providing an electrical signal to at least one of said pins in the event of a detected conflict.

6. Method of performing refreshing concurrently with reading or writing of a Dynamic Random Access Memory comprising memory cell refresh means, comprising the steps of:
detecting if there is a conflict between a read or write access and a refresh access for a given memory cell,
communicating an error signal if there is a conflict,
reissuing the read or write access to said cell in case the conflict was caused by a read or write access during an ongoing refresh access to said cell and
delaying the refresh access to said cell in case the conflict was caused by a refresh access during an ongoing read or write access to said cell.

7. Dynamic Random Access Memory suitable for use in an electrical circuit as claimed in claim 1.
